(19) United States
(12) Patent Application Publication
(10) Pub. No.: US 2002/0006677 A1
(43) Pub. Date: Jan. 17, 2002

(54) Detection of contaminants on semiconductor wafers

(75) Inventors: John Egermeier, San Jose, CA (US); Vikash Banthia, Los Altos, CA (US); Paul Kiely, San Francisco, CA (US); Karl Armstrong, Santa Cruz, CA (US)

Correspondence Address: Patent Counsel, Applied Materials, Inc., 3050 Bowers Avenue, P. O. Box 450A, Santa Clara, CA, 95052, US

(73) Assignee: Karl Armstrong

(21) Appl. No.: 09/752,805

(22) Filed: Dec. 29, 2000

Related U.S. Application Data
(63) Continuation of application No. 09/343,937, filed on Jun. 30, 1999, now abandoned.

(51) Int. Cl. H01L 21/66; G01R 31/26; H01L 21/44

(52) U.S. Cl. 438/14; 438/680; 438/908

(57) ABSTRACT

A method and apparatus for analyzing and comparing in real-time the presence of contaminants in a semiconductor substrate processing system. The analysis is made and compared against a statistical baseline of data points established from the analysis of acceptable substrates undergoing the same procedure. A decision can then be made as to whether to remove the wafers for reprocessing. The comparison is to be made not only with the above baseline, but also in accordance with process dependent information provided by a supplemental data port in the processing tool. Thus, the baseline is dynamic and not a static, pre-determined figure.

### FIELD OF THE INVENTION

The invention relates to semiconductor wafer processing and more particularly to a method of detecting in real time the presence of contaminants on wafers and their related cassettes as the wafers are being admitted to or being processed in a semiconductor wafer processing tool.

### BACKGROUND OF THE INVENTION

The escalating requirements of density and performance associated with ultra large scale integrated circuits require that wafers upon which such circuits are constructed be free of any contaminants during the processing thereof, particularly during certain operations, such as chemical vapor deposition (CVD) of metal. Those of ordinary skill in the art recognize that, regardless of the original state of cleanliness that a wafer possesses upon entering into the complex recipe of steps required in its processing, it is possible that a wafer and/or its related cassette might become contaminated during processing, regardless of the precautions taken to prevent such an occurrence.

The most common mechanism whereby such contamination occurs is through the incomplete removal of resist material that is used for insulating or barrier layers, etch-stop layers and the like. For example, common insulating resist materials are silicon dioxide, silicon nitride and “low K dielectrics” such as amorphous fluorinated carbon (a-C:F). These materials are applied to a wafer, masked and exposed to an energy beam (e.g. electron, x-ray or the like) to develop portions of the material. The wafer is then subjected to one or more etch steps and chemical rinses to create the desired circuit and remove the resist upon completion of the fabrication. Failure to totally remove a layer of resist material can result in alteration or loss of the properties of subsequently deposited layers, loss of adherence of subsequently deposited layers, and/or overall diminishing of the effectiveness of the final device formed upon the wafer. In modern submicron technology, anything that will significantly alter the beneficial properties of the device to be formed upon a wafer is detrimental and must be removed.

Semiconductor processing such as described above typically is carried out in specialized apparatus comprised of multiple chambers wherein wafers are processed by the deposition and various treatments of multiple layers of semiconductor material in a single environment. In such tools, the plurality of processing chambers and preparatory chambers are arranged in clusters, each served by robotic transfer means. Hence, such tools are commonly referred to as cluster tools. Such tools process semiconductor wafers through a plurality of sequential steps to produce integrated circuits. In such tools, it is inherently very difficult to ascertain on-line and in real time whether a resist or other similar layer or structure has actually been totally removed so that there is no residue that can exert a deleterious effect on subsequent processing steps or the operation of the device (i.e., circuit) to be fabricated on the wafer.

Those of ordinary skill in the art are aware that there is methodology available that can be utilized to ascertain, outside of the reaction chamber, that a given wafer is free of contamination. However, such methods are not effective in determining whether a wafer has become contaminated while it is in transit among the various chambers within a cluster tool, or after it has entered such a specialized apparatus. Clearly, it would be particularly beneficial to have a means of identifying contaminated wafers in situ, i.e. without the necessity of removing the wafer from the processing apparatus and/or exposing it to elements present in the atmosphere that might further contaminate it. Such an in situ determination is of significant advantage with regard to cluster tools. The economics of such devices would be severely compromised were it necessary to shut down the tool while it is determined whether wafers being processed have become contaminated and, if so, remove them. A methodology to overcome the disadvantages of the prior art is provided in accordance with the present invention.

### SUMMARY OF THE INVENTION

The invention overcomes the disadvantages associated with the prior art by providing a process wherein wafers undergoing degassing preceding or during a processing sequence in a multichamber processing tool, or upon entering a specialized processing apparatus are heated to a temperature sufficient to volatilize any contaminants thereon or therein, analyzing the resultant gases in real-time for the presence of contaminants, comparing the analysis against a baseline of data points established from the analysis of acceptable wafers undergoing the same procedure and initiating a decision on whether to remove the wafers for reprocessing. The comparison can be made not only by the above baseline, but also in accordance with process dependent information provided by a supplemental data port in the processing tool. In this way, the baseline is a dynamic range that accounts for various process variables and not a static, pre-determined, absolute figure that may unnecessarily reject acceptable wafers.

The invention is also directed to a general purpose computer system that operates as a special purpose controller when executing a program of heating wafers during degassing preceding or during processing in a specialized or multifunctional apparatus to volatilize contaminants and thereby form effluent therefrom, comparing the effluent against a statistical baseline established for acceptable wafers having the same characteristics and undergoing the same procedures, generating a signal when the effluent of the wafer exceeds said statistical baseline and initiating a decision to remove such wafer from further processing. The statistical baseline data varies according to the wafer pre-processing condition and the process sequence being used. The system is further provided with process dependent information from a supplemental data port such as a SECS port in the apparatus.

The invention further includes an apparatus for the in-situ determination of contaminants and contains a multichamber semiconductor processing tool, a control unit connected to the processing tool and a supplementary information port disposed upon one or more of the chambers of the processing tool. The method and apparatus analyze and compare effluent levels of a substrate to a statistically established baseline of acceptable effluent levels taking into consideration the processing steps and conditions of the particular process sequence being performed on the substrate and generates a signal when the effluent level exceeds the statistical baseline threshold. Since the statistical baseline is variable by wafer condition and process sequence, and the process sequence of the particular wafer is considered, the criteria by which the substrate is evaluated is more accurate; hence, fewer improperly rejected substrates will result during processing.

### BRIEF DESCRIPTION OF THE DRAWINGS

The teachings of the present invention can be readily understood by considering the following detailed description in conjunction with the accompanying drawings, in which:

FIG. 1 illustrates a sequence of steps in carrying out the testing procedure of the present invention;

FIG. 2 illustrates a block diagram of a control system that is employed in accordance with the present invention to control the testing and further processing of wafers in accordance with the present invention;

FIG. 3 illustrates a multichamber semiconductor processing cluster tool modified to carry out the procedure of the present invention;

FIG. 4 depicts a top graph of a specific gas pressure vs. time and a bottom graph of specific gas pressure vs. amount of mass (amu) for a “clean” wafer;

FIG. 5 depicts a top graph of a specific gas pressure vs. time and a bottom graph of specific gas pressure vs. amount of mass (amu) for a wafer after dielectric etch, but prior to deposition;

FIG. 6 depicts the graphs similar to that of FIG. 5 with an overlayed alarm message;

FIG. 7 depicts a graph of two specific gas pressures vs. time; and

FIG. 8 depicts a top graph of a specific gas pressure vs. time and a bottom graph of specific gas pressure vs. amount of mass (amu) for a wafer after CVD Tungsten etchback of a TiN layer.

### DETAILED DESCRIPTION OF THE PREFERRED EMBODIMENTS

In accordance with the present invention, there is provided a means of accurately determining whether a wafer and/or its related cassette has become contaminated during semiconductor processing, as by the incomplete removal of a material such as a resist or barrier layer. Another possible source of contamination is low K dielectric material. As will be discussed hereafter, this material is very porous and must be adequately annealed in order to remain stable through processing and subsequent use. Annealing removes or chemically alters substances entrapped in such material. While such substances are not necessarily contaminants, their removal or conversion is essential to the proper function of the final device.

The advantage of the methodology provided in accordance with the present invention is the substantial reduction in the number of false positives that result as compared to inventions of the prior art. For example, in the prior art, a conventional residual gas analyzer is attached to a degassing chamber and an analysis of the effluent is conducted. By conventional is meant a device that would simply analyze the effluent of the chamber. The reason for the comparatively high instance of false positives —a positive being defined as a signal that a wafer is contaminated —is that the effluent constantly undergoes a progressing change and the makeup of the materials deposited on the wafer changes.

An example of a variation that will be experienced in the determination of contamination via the methodology described herein is the instance where a tray of a hundred or more wafers is inserted into the load-lock chamber of a semiconductor processing tool which is then evacuated after which the wafers are individually taken into the degassing chamber. The first wafers taken in will give off substantially more gas than those that have been in the loadlock chamber under vacuum for up to an hour or more waiting their turn to enter the processing sequence. Also, where a wafer has received several layers of material, such as a low K dielectric material, the makeup of such layers and/or gases entrained therein can markedly influence the makeup of the effluent.

In accordance with the present invention, the problem of false positive readings generated by the variables described above is addressed by providing an extensive baseline of data points accumulated by the testing of many acceptable wafers which is assimilated into a computer readable software program. The baseline provides, for example, variation in the readings as would be experienced from the first to the last of one hundred or more wafers being individually introduced into a degassing chamber from a load-lock chamber under vacuum. The baseline also integrates variations resulting from the presence of one or more layers of material on the wafers as well as variations in the material itself, e.g., low K dielectric material such as SILK™, BLACK DIAMOND™ and the like.

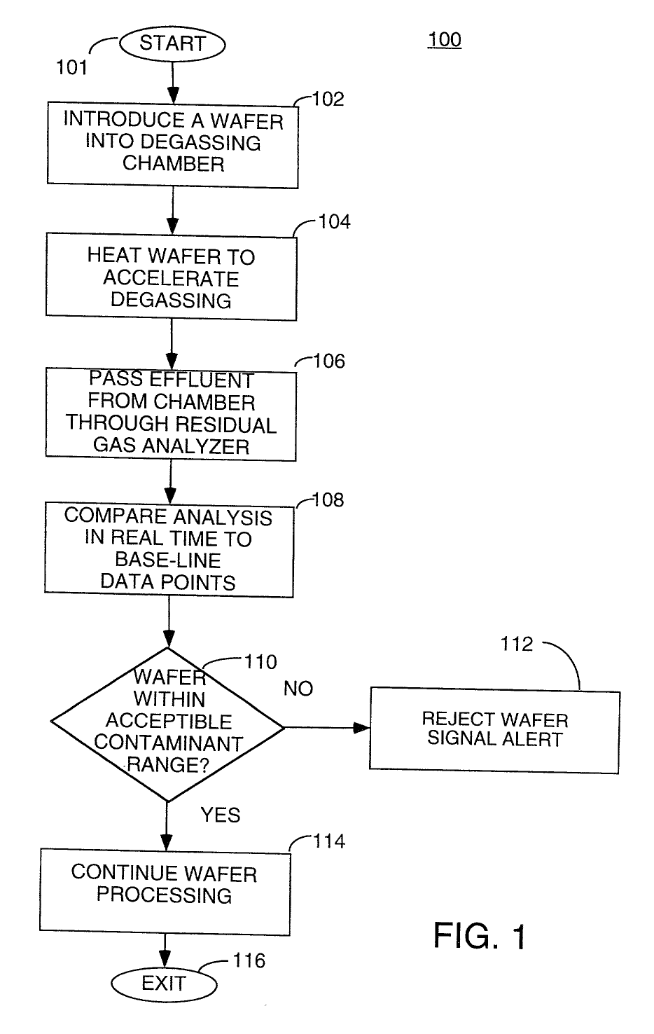

The above-described method for detecting wafer contaminants is depicted as a series of process steps 100, in FIG. 1. As shown in FIG. 1, the method 100 starts at step 101 and proceeds to step 102 where a wafer under vacuum in a load-lock chamber of a semiconductor processing tool is introduced into a degassing chamber. The wafer is then heated, such as by an infra-red lamp, to accelerate the degassing process in step 104. Generally, the temperature utilized must be high enough to accomplish rapid degassing of the wafers (i.e., volatilize contaminants), but not so high as to damage the wafers or the circuitry being constructed thereon. A suitable temperature range for accomplishing degassing is from about 100° C. to 500° C. and preferably 350° C.

In step 106, the effluent from degassing step 104 is analyzed. Specifically, effluent (i.e., the volatilized contaminants) is passed in real-time through a residual gas analyzer (RGA) and assigned a corresponding effluent data point. Those of ordinary skill in the art are aware of such an apparatus and will appreciate that the efficiency of the subject process increases with the sensitivity of measurement of the residual gas analyzer. An example of a suitable RGA is RESIST TORR manufactured and sold by SPECTRA. Such apparatus has a sensitivity of at least about 5e⁻¹⁰ Torr, with a high degree of repeatability.

The effluent data point of the residual gas analyzer is compared in step 108 to established, acceptable baseline effluent levels. The baseline is comprised of a plurality of data points collected from hundreds of acceptable wafers having the same characteristics and undergone the same processing steps as the currently tested wafer. Preferably, the analysis is performed by a statistical engine, i.e., an executable software program generally executed on a general purpose computer, or a subroutine executed within the microprocessor of a control unit, which correlates information collected about the effluent from the residual gas analyzer.

At step 110, a decision is made as to whether the wafer (via the effluent data point) is within the baseline. The requisite comparison is in real-time and generates a signal in the event the analysis indicates contamination of the wafer. In such event, the wafer is rejected from subsequent processing in step 112 (i.e., is withdrawn for reprocessing, such as by being returned to the prior processing operation carried out to remove residual layers). In the absence of a signal indicating contamination, the wafer is forwarded, typically by robotic transfer means, to the next operation in the processing sequence in step 114. The method of the present invention ends at step 116.

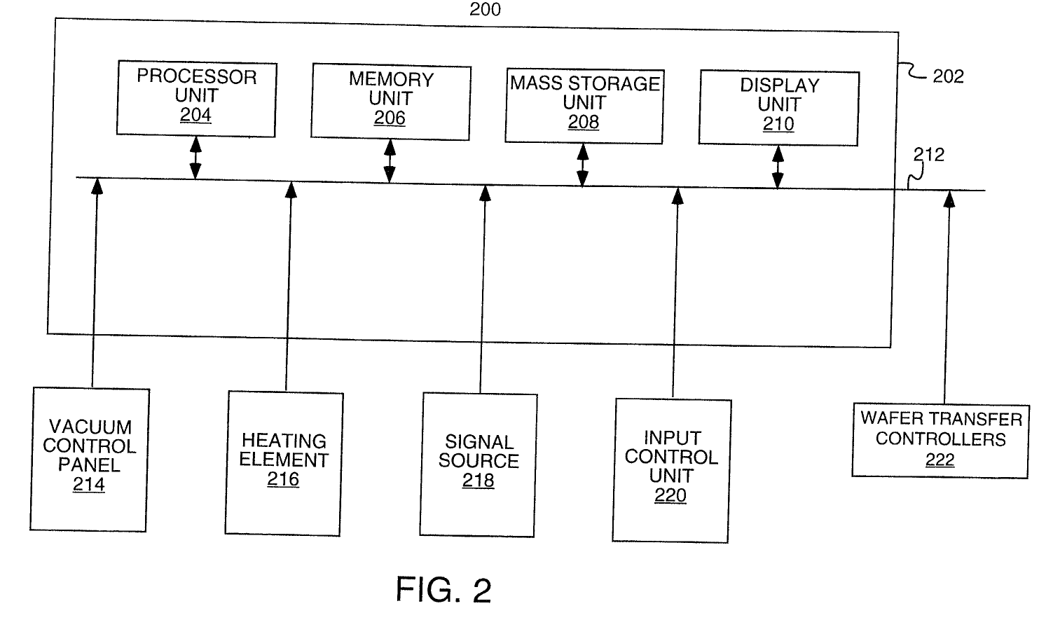

The above-described process steps, as illustrated in FIG. 1, are advantageously performed in a system that is controlled by a processor-based control unit. FIG. 2 shows a block diagram of a deposition system 200 having a control unit 202 that can be employed in such a capacity. The control unit 202 includes a processor unit 204, a memory 206, a mass storage device 208, an input control unit 220, and a display unit 210 which are all coupled to a control unit bus 212. Although the control unit bus 212 is displayed as a single bus that directly connects the devices in the control unit 202, the control unit bus 212 can also be a collection of buses, or can itself be part of a collection of busses.

The processor unit 204 may be a general purpose computer such as described above, or may be a subroutine executable within a microprocessor or other statistical engine of the system controller for the overall processing of the wafers. The processor unit 204 is capable of making the comparison of effluent data points to the baseline as described above and initiating the requisite instructions based thereon. The processor unit 204 forms a general purpose computer that becomes a specific purpose computer when executing programs such as a program for detecting contaminants on a wafer in accordance with the present invention. Although the invention is described herein as being implemented in software and executed upon a general purpose computer, those skilled in the art will realize that the method of the present invention could be operated using hardware such as an application specific integrated circuit (ASIC) or other hardware circuitry. As such, the invention should be understood as being able to be implemented, in whole or in part, in software, hardware or both.

The memory 206 can be comprised of a hard disk drive, random access memory (“RAM”), read only memory (“ROM”), a combination of RAM and ROM, or another processor readable storage medium. The memory 206 contains instructions that the processor unit 204 follows to execute the above mentioned process steps and various others not specifically stated but include steps such as activating a vacuum control panel 214, a heating element 216 and a signal source 218. The instructions in the memory 206 are in the form of program code. The code of which the instructions are written may conform to any one of a number of different programming languages. For example, the program code can be written in C+, C++, BASIC, Pascal, or a number of other languages.

The mass storage device 208 contains the established, acceptable baseline which comprises a plurality of data points based on hundreds of previously processed wafers. As such, an operator can set a program for the number of wafers being individually processed into the equipment and the degree of processing they have already undergone in terms of process steps, materials deposited thereon and materials used in various treatment steps, e.g. plasma annealing and the like.

The display unit 210 provides information to a chamber operator in the form of an audible signal, a graphic display or the like that indicates the wafer being tested is contaminated. The input control unit 220 couples a data input device, such as a keyboard, mouse, or light pen, to the control unit 202 via electrical lines (not shown) to provide for the receipt of input from an operator or from the computer system operating a cluster tool. Each of the elements is coupled to the control unit bus 212 to facilitate communication between the control unit 202 and the elements. Once analysis of the degassing step has taken place and the requisite comparison made in real-time with the baseline provided in mass storage unit 208, the wafer is automatically forwarded for the next programmable processing step by wafer transfer controller 222. In the event a signal has been generated by display unit 210, wafer transfer controller 222 may automatically reject the wafer from the system, or submit the decision to remove to operator discretion.

The method of the present invention is of particular advantage when incorporated into a multifunction semiconductor cluster tool. Examples of suitable cluster tools capable of performing the in-situ testing procedure of the present invention in the manner described are the Endura® and Centura® 5200 systems manufactured and sold by Applied Materials, Inc. of Santa Clara, Calif.

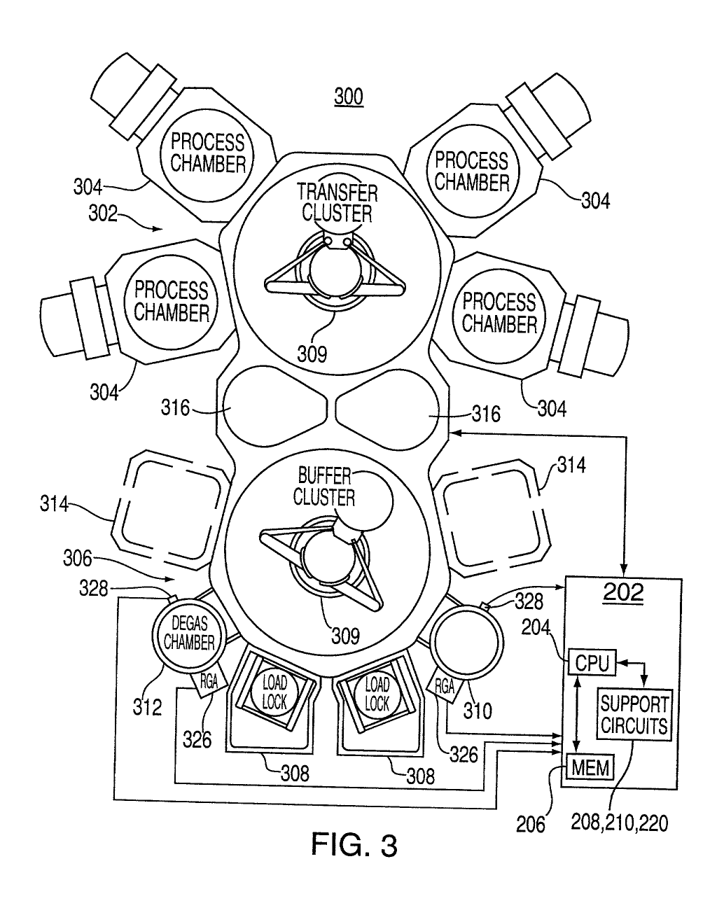

FIG. 3 depicts a cluster tool 300 similar to an Endura® System. The tool 300 is comprised of a transfer cluster 302 and a buffer cluster 306. The transfer cluster 302 further comprises a plurality of process chambers 304 wherein wafers are processed. In a preferred embodiment of the invention, the plurality is four and the chambers perform CVD metallization. The buffer cluster 306 further comprises at least one, preferably two load-lock chambers 308 which admit and withdraw wafers from the tool 300, a wafer orientation/degas chamber 310 and a second degas chamber 312. Optionally and as denoted by dashed lines, the buffer cluster 306 further comprises one or more cleaning chambers 314 for sputter cleaning the wafers. The transfer cluster 302 and the buffer cluster 306 each contain robotic wafer handling mechanisms 309 that transport the wafers among the chambers within their respective clusters. Separating the transfer cluster 302 and the buffer cluster 306 is at least one transition chamber, for example, the pass-through chambers 316. These transition chambers may simply convey the wafers between the clusters or may perform functions in their processing. A control unit 202 controls the operation of the cluster tool 300. The control unit 202 is as described above. The programs executed by the control unit 202 cause the cluster tool 300 to perform various operations as discussed below.

Each of the degassing chambers 310 and 312 contains a heating means (not shown) such as an infrared lamp, a residual gas analyzer 326 that analyzes the effluent from the degassing procedure in real-time and a supplemental data port 328. The RGA 326 transmits the effluent data points into the control unit 202 where they are compared with the baseline as discussed above. The supplemental data port 328 transmits specific process dependent information to the control unit 202 (i.e., wafer processing sequence and recipe names, wafer lot ID and wafer slot ID). The advantage realized by this additional data port is that effluent data points are not analyzed according to and compared against a static or predisposed value. Instead, a statistical baseline range of acceptable values which has been pre-established for the process sequence and wafer condition is referenced according to the information provided by the supplemental data port 328. Such capabilities result in a reduced number of “false positive” contamination alerts. That is, as processing continues, the value of acceptable contaminants becomes a range (i.e. ±3δ). Wafers having effluent data points outside this range (i.e., ±3.2δ) would ultimately be rejected; however, wafers having effluent data points not falling directly at a “zero” level (i.e., ±2.9δ which could constitute a false contaminant condition) would still fall within the acceptable range. In a preferred embodiment of the invention, the supplemental port 328 is a SECS port.

The first degas chamber 310, which also functions as a wafer orienting chamber, checks the wafers for contamination as they are withdrawn from the loadlock chamber 308 and introduced into the buffer cluster 306. The second degas chamber 312 functions to determine contamination on wafers at a point in processing when there is the possibility they may have become contaminated, as through the incomplete removal of a resist layer. In a large cluster tool performing multiple steps to build complex circuitry on wafers, additional degas chambers can be incorporated into the procedure as required to assure that the wafers have not become contaminated during processing.

In operation, wafers are carried from storage to the cluster tool 300 in a plastic transport cassette that is placed within one of the loadlock chambers 308. The robotic transport mechanism 309 within buffer chamber 306 transports the wafers, one at a time, from the cassette to the wafer orienting/degas chamber 310 wherein degassing is accelerated by heating the wafer. The effluent from degassing of the wafer is analyzed by the residual gas analyzer 326 and the analysis compared against the baseline described above taking into account the supplemental data port information. Wafers passing the contamination test, i.e., within the baseline range, are removed by the robotic transport mechanism 309 and processed according to the sequence programmed into the control unit 202. The wafers may undergo additional preparatory procedures in the buffer cluster 306 or may pass through the transfer chambers 316 into the transfer cluster 302 for processing.

In the event that a processing step has required that a pattern layer be utilized to deposit a given material on a wafer and it is desired to ascertain whether the pattern layer has been totally removed once its function is completed, the wafers may be individually returned to the buffer cluster 306 and admitted to degas chamber 312. In degas chamber 312, the process of heating and analysis is repeated although the analysis is compared against the baseline as well as information from the supplemental data port wherein such information is not necessarily the same in formation seen at the supplemental data port in the wafer orienting/degas chamber 310. Since the wafer has undergone various process steps since last being checked in chamber 310, it may be minimally contaminated but still acceptable. A static baseline comparison would reject such a wafer. However, the supplemental data port information compensates for any variances to reduce falsely rejected wafers. In each instance, if the configuration of the tool will permit, there may be provided cleaning chambers where wafers indicating contamination may be treated to remove the contamination and thereafter returned to the appropriate degas chamber for retesting. Alternatively, wafers showing contamination may simply be removed from the tool by an appropriate mechanism not shown.

It has been found that the detection method of the present invention, being based on data points accumulated through the processing of many acceptable wafers, produces an exceptionally low incidence of false positive readings. The methodology of the invention may be utilized in a multifunction tool such as a cluster tool, or as a first stage in a specialized tool, such as a CVD metallization device. Specifically, the usefulness of statistical baselining of outgassing profiles can be used for the pre-process screening of substrates for production population quality matching in a variety of different process tool types including but not limited to: ETCH, CVD (i.e., metal or dielectric), EPI (epitaxial deposition), Ion Implantation and RTP (rapid thermal processing). For each tool type and/or process, there is a specific statistical baseline used to confirm a substrate's condition as part of a normal distribution or acceptable contaminant range. These baselines are integrated (i.e., loaded in as a software database file or hardware memory circuit) into the tool or system to practice a variety of contaminant detection operations.

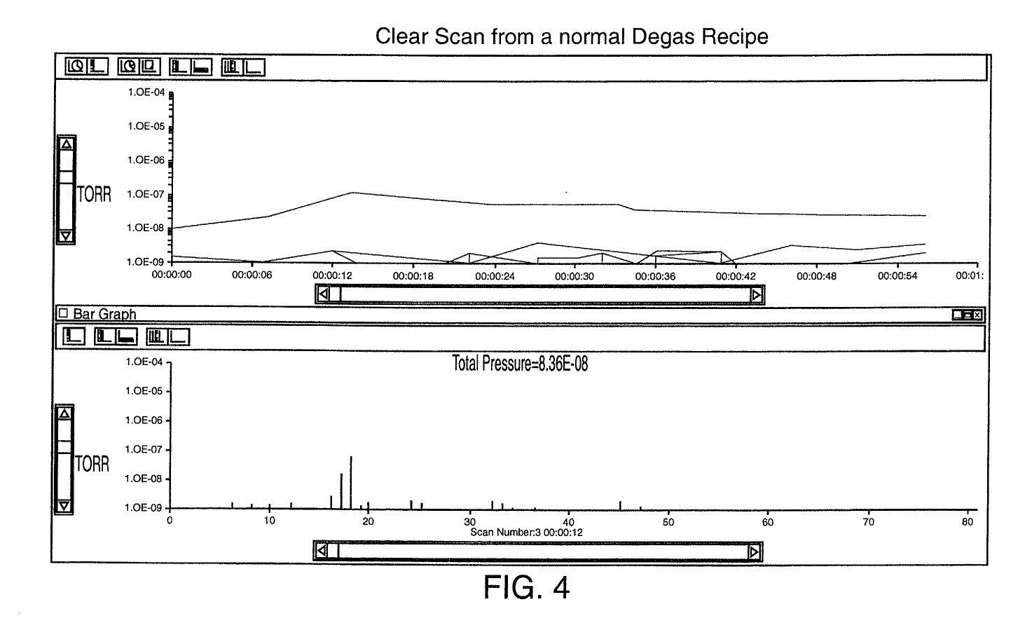

In order to determine acceptable contaminant levels from unacceptable ones, it is essential first to define the statistical baseline. FIG. 4 shows a data file of a clean wafer during degas. The degas recipe used is 30 seconds at 40% power and 30 seconds at 60%. The top graph shows variation in a specific gas pressure over time and the bottom graph shows a single scan of the entire mass range at a given instant. Water (x=18, 17, 16 in the bottom graph) is the principle outgassing species and there is no indication of organic contamination. Because of the connection of the supplementary information port 328 to the control unit 202, a data file (not shown) can also store the lot number, wafer number and the recipe name of the process. This will allow the data to be correlated with other information such as reflectivity or sheet resistance and other device related data of the wafer, greatly enhancing the understanding of the process flow.

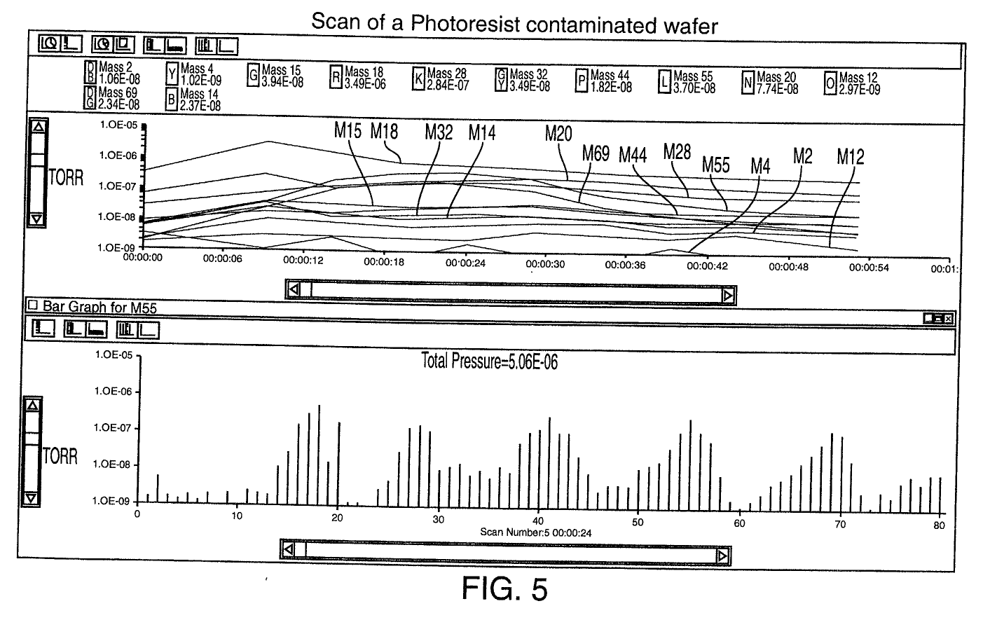

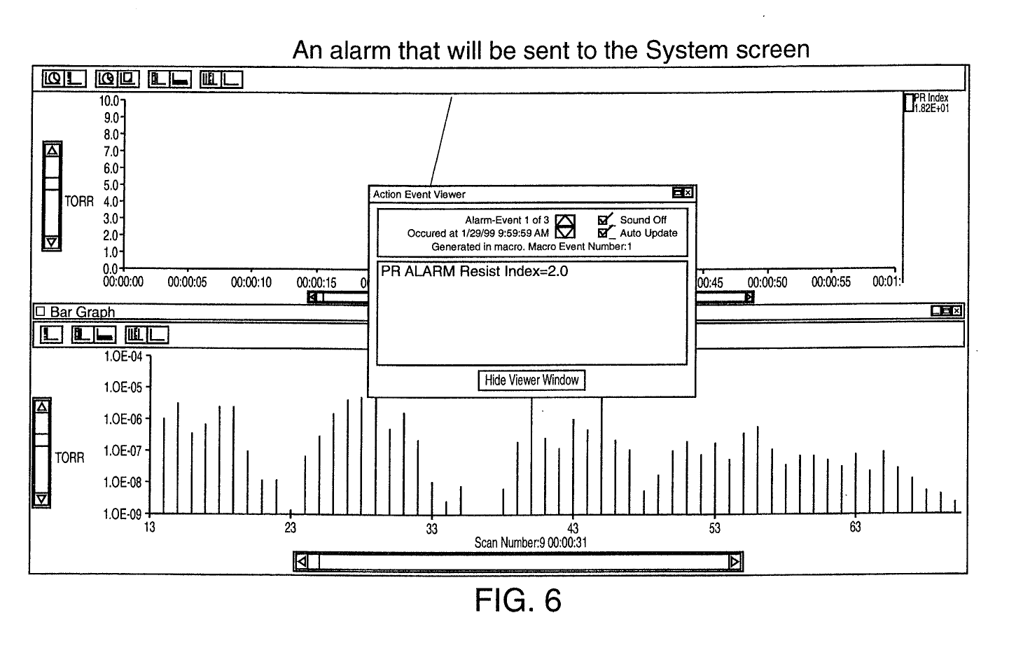

FIG. 5 shows a scan of a wafer after dielectric etch and before adhesion layer deposition. The degas recipe is identical to that in FIG. 4. The presence of photoresist is seen in the distinctive hydrocarbons peaks from the mass range 20 amu to 70 amu in the bottom graph. These high peaks can be used to generate an alarm which prevents further wafer processing in the tool 300. FIG. 6 shows an alarm message which indicates a resist index of 2. This means the alarm criterion (data point(s) outside the statistical baseline range) has been exceeded by a factor of 2. It is within the scope of the present invention that the index level can be adjusted to meet the individual requirements of a particular manufacturing site.

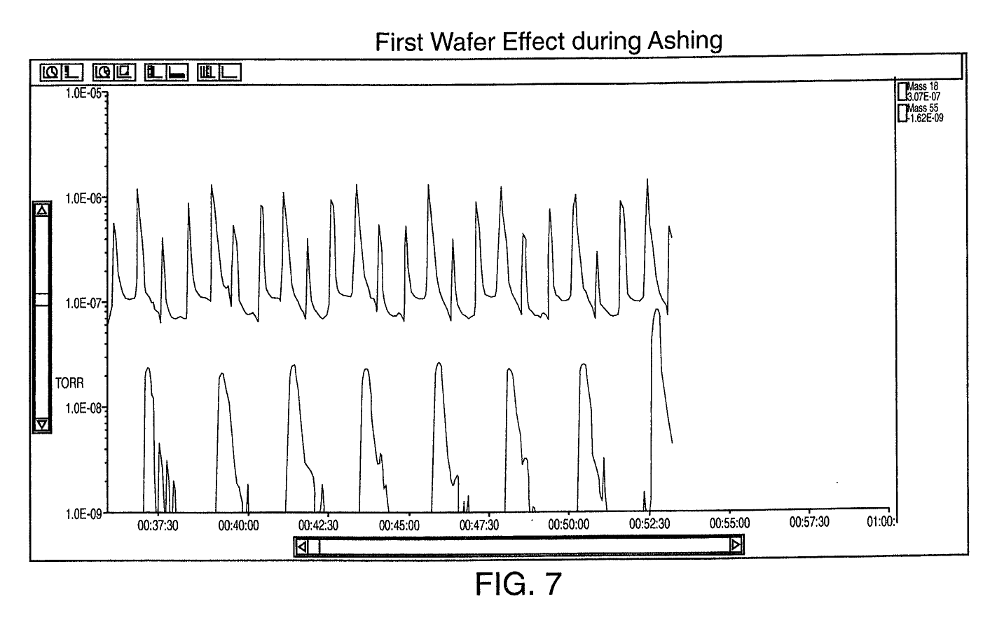

FIG. 7 shows a scan of multiple wafers in the form of a trend chart. Line 702 (mass 18) on the top graph indicates the variation in the water level due to slit valves opening and closing in the tool 300 and degas events. Line 704 (mass 55) is a constituent of a photoresist. The last wafer in the scan shows nearly an order of magnitude increase in the level of photoresist. In one particular example, this happens to be the first wafer ashed in an ashing tool. It has been since determined that this ashing tool has a cold chamber effect which reduces the reliability of the ash on the first wafer. Modification to the ashing process has eliminated this problem in that particular production facility. This is an example of the use of the RGA information to affect the overall process flow and improve production.

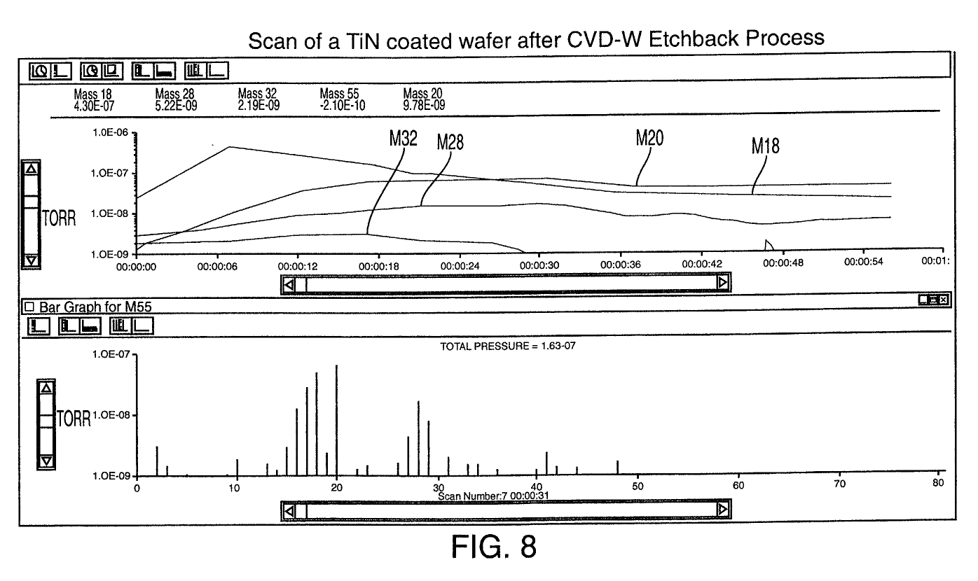

FIG. 8 shows a scan of a TiN coated wafer after a CVD-Tungsten (W) etchback process with NF₃. The degas recipe is similar to the one previously mentioned. In comparing this scan with FIG. 4, a significant peak at mass 20 is noted in the bottom graph. This 20 peak is an indication of HF outgassing. Fluorine was absorbed into the porous TiN film during the etchback process and is released during wafer heating in the degas process. At this point, sufficient information is not available to establish the possible negative impact of this level of HF on the devices. However, the stability of the process at this point in the flow can be monitored. Large variations in the HF level can be tracked against variations in device performance or reliability in order to provide upper control limits on the allowable levels of HF. Furthermore, any variations of similar signatures can be identified and process control put in place in order to eliminate the adverse effects of these variations.

Although the present invention has been described in terms of particular embodiments, numerous changes can be made thereto as will be known to those skilled in the art. The invention is only meant to be limited in accordance with the limitations of the appended claims.

What is claimed is:

1. A method for the in-situ determination of the presence of contaminants on a semiconductor substrate undergoing a sequence of processing operations in a processing tool, the method comprising the steps of:
(a) withdrawing the substrate from the sequence and heating it to an elevated temperature such that at least one of the contaminants present is volatilized;
(b) determining the amount of said at least one contaminant volatilized by the heating step;
(c) comparing the amount of said at least one contaminant against acceptable amounts; and
(d) wherein the amount of said at least one contaminant is within said acceptable amounts, returning said substrate to the sequence.

2. The method of claim 1, wherein the amount of said at least one contaminant exceeds said acceptable amounts, the method further comprising the step of recycling the substrate to an earlier stage in the sequence wherein substrates are treated to remove contaminants.

3. The method of claim 1, wherein the amount of said at least one contaminant exceeds said acceptable amounts, the method further comprising the step of removing the substrate from the sequence.

4. The method of claim 1 wherein said at least one contaminant is a residue from a resist layer.

5. The method of claim 4, wherein the said at least one contaminant exceeds said acceptable amounts, the method further comprising the step of recycling the substrate to the step in the sequence where the resist is removed therefrom.

6. The method of claim 1 wherein step (b) further comprises analyzing effluent and assigning said effluent a data point.

7. The method of claim 6 wherein step (c) further comprises comparing said effluent data point to a statistical baseline of acceptable effluent levels.

8. The method of claim 7 wherein said statistical baseline further comprises a plurality of data points collected from a plurality of wafers having acceptable contaminant levels.

9. The method of claim 1 wherein step (c) further comprises comparing the amount of said at least one contaminant against acceptable amounts and with regard to process dependent information.

10. The method of claim 9 wherein said process dependent information is selected from the group consisting of wafer processing sequence, wafer recipe name, wafer lot ID number, wafer slot ID number.

11. The method of claim 9 wherein said process dependent information is provided by a SECS port in the processing tool.

12. In a system for controlling the process sequence of wafers through a semiconductor processing tool containing a plurality of chambers, at least one of which is performing an in situ determination of the presence of at least one contaminant on wafers being processed therein, a general purpose computer system that operates as a special purpose controller when executing a program for such chamber stored in a computer readable medium to perform a process therein comprising the steps of:
a) h eating the wafer in the chamber to a temperature such that said at least one contaminant is volatilized thereby forming effluent;
b) determining the amount of s aid effluent present in the atmosphere in the chamber;
c) comparing the amount against amounts thereof in acceptable wafers; and
d) invoking a decision to further process the wafer in the sequence.

13. The general purpose computer system of claim 12 wherein step (b) further comprises assigning the effluent a data point.

14. The general purpose computer system of claim 13 wherein step (c) further comprises comparing the effluent data point to a statistical baseline of acceptable effluent levels.

15. The general purpose computer system of claim 14 wherein said statistical baseline further comprises a plurality of data points collected from wafers having acceptable contaminant levels.

16. The general purpose computer system claim 12 wherein step (c) further comprises comparing the amount of effluent against acceptable amounts and with regard to process dependent information.

17. The general purpose computer system of claim 16 wherein the process dependent information is provided by a SECS port in the processing tool.

18. An apparatus for the in-situ determination of the presence of contaminants on a semiconductor substrate comprising:
a multichamber processing tool;
a control unit connected to the processing tool; and
a supplementary information port disposed upon one or more of the chambers of said processing tool and connected to the control unit.

19. The apparatus of claim 18 wherein said supplementary information port is a SECS port.
